(19) United States
(12) Patent Application Publication
(10) Pub. No.: US 2012/0273861 A1
(43) Pub. Date: Nov. 1, 2012

(54) METHOD OF DEPOSITING GATE DIELECTRIC, METHOD OF PREPARING MIS CAPACITOR, AND MIS CAPACITOR

(75) Inventors: Xinhong Cheng, Shanghai (CN); Dawei Xu, Shanghai (CN); Zhongjian Wang, Shanghai (CN); Chao Xia, Shanghai (CN); Dawei He, Shanghai (CN); Zhaorui Song, Shanghai (CN); Yuehui Yu, Shanghai (CN)

(73) Assignee: SHANGHAN INSTITUTE OF MICROSYSTEM AND IMFORMATION TECHNOLOGY,CHINESE ACADEM, Shanghai (CN)

(21) Appl. No.: 13/256,435

(22) PCT Filed: Jun. 8, 2011
(86) PCT No.: PCT/CN2011/075440

§ 371 Date: Sep. 13, 2011

(30) Foreign Application Priority Data
Apr. 29, 2011 (CN) 201110110338.9

(51) Int. Cl. H01L 29/94; H01L 21/334; H01L 21/3105

(52) U.S. Cl. 257/310; 438/763; 438/393; 257/E29.345; 257/E21.396; 257/E21.241

(57) ABSTRACT

The present invention relates to a method of depositing a gate dielectric, a method of preparing a MIS capacitor and the MIS capacitor. In the method of depositing the gate dielectric, a semiconductor substrate surface is preprocessed with oxygen plasma and nitrogen-containing plasma to form a nitrogen-containing oxide layer thereon. Then, a high-k gate dielectric layer is grown on the nitrogen-containing oxide layer surface by a plasma-enhanced atomic layer deposition process, and the oxide layer converts during the gate dielectric layer growth process into a buffer layer of a dielectric constant higher than SiO₂. Then, a metal electrode is formed on both an upper layer and a lower layer of the thus-formed semiconductor construction, so that a MIS capacitor is prepared. According to the present invention, the formation of the buffer layer enables the interface characteristics between semiconductor materials and high-k gate dielectric layers to be improved effectively, equivalent oxide thickness (EOT) to be reduced and electrical properties to be enhanced.

### FIELD OF THE INVENTION

The present invention relates to a semiconductor field, and more particularly to a method of depositing a gate dielectric, to a method of preparing a MIS capacitor and to the MIS capacitor.

### BACKGROUND OF THE INVENTION

A SiO₂ gate dielectric layer has become thinner and thinner with the rapid development of microelectronic technology. However, when a thickness of the SiO₂ gate oxide layer is less than 1 nm, a leakage current caused by direct tunneling effect may become high enough to induce device failure. And moreover, an ultra-thin SiO₂ gate dielectric layer is limited in properties such as its long-term reliability, boron penetration, and uniformity. Presently, one of the effective ways to overcome the above limitations is to utilize a new insulation dielectric material (high-k material) of a high dielectric constant. Utilizing the high-k material may lead to an increase in the thickness of the gate dielectric layer with the control over channels ensured, thus effectively overcome the above limitations. Hafnium oxide (HfO₂) is one of the most promising gate oxides because of its high dielectric constant k (which is approximately 25), its relatively large forbidden-band gap as well as the good thermal stability between it and a Si substrate.

Atomic layer deposition (abbreviated as ALD), which is generally regarded as the method of choice to grow gate dielectric materials in the art, is the most probable method of depositing a high-quality high-k gate dielectric layer in consideration of its self-limiting characteristics in growing film, accurate control of thickness and chemical compositions of a grown film, and good uniformity and shape preserving property of a deposited film. In comparison with the conventional ALD thermal growth process, plasma-enhanced atomic layer deposition (abbreviated as PEALD) may utilize plasma to increase reactant activities and has a wider reaction temperature range, thus depositing a film of a higher density. However, the HfO₂ film grown by the conventional ALD process or PEALD process and its substrate have an unavoidable low dielectric-constant SiO₂ layer sandwiched therebetween, and the SiO₂ layer grows further during an annealing process. In addition, the HfO₂ film usually has lots of oxygen vacancies contained therein, resulting in an increase in equivalent oxide thickness (abbreviated as EOT) and deterioration in electrical properties.

Therefore, there is an urgent need to solve the above existing problems in preparing the gate dielectric layer.

### SUMMARY OF THE INVENTION

An object of the invention is to provide a method of depositing a gate dielectric so as to reduce the equivalent oxide thickness and improve electrical properties.

Another object of the invention is to provide a MIS capacitor and a method of preparing the MIS capacitor.

To achieve the above objects and others, the invention provides a method of depositing a gate dielectric by a plasma-enhanced atomic layer deposition process, comprising a preprocess step of pre-processing a surface of a semiconductor substrate with oxygen plasma and nitrogen-containing plasma to form a nitrogen-containing oxide layer thereon; and a growth step of growing a high-k gate dielectric layer on a surface of the nitrogen-containing oxide layer by the plasma-enhanced atomic layer deposition process, wherein the nitrogen-containing oxide layer converts into a buffer layer of a dielectric constant higher than SiO₂ during the gate dielectric layer growth process.

The invention provides a method of preparing an MIS capacitor comprising: a preprocess step of pre-processing a surface of a semiconductor substrate with oxygen plasma and nitrogen-containing plasma to form a nitrogen-containing oxide layer thereon; a growth step of growing a high-k gate dielectric layer on the semiconductor construction surface having the oxide layer by the plasma-enhanced atomic layer deposition process, the nitrogen-containing oxide layer converting into a buffer layer of a dielectric constant higher than SiO₂ during the gate dielectric layer growth process; and a step of forming a metal electrode on both an upper surface and a lower surface of the semiconductor construction having the gate dielectric layer deposited thereon.

The invention provides a MIS capacitor comprising a semiconductor substrate, a buffer layer of a dielectric constant higher than SiO₂ and a gate dielectric layer arranged between two metal electrodes in sequence.

To sum up, in the method of depositing the gate dielectric by the plasma-enhanced atomic layer deposition process of the present invention, the Si substrate is preprocessed with oxygen plasma and nitrogen-containing plasma to form a buffer layer of a relatively high dielectric constant at an interface of the gate dielectric layer, thus effectively leading to a reduction in equivalent oxide thickness and an improvement in electrical properties.

### BRIEF DESCRIPTION OF THE DRAWINGS

Other and further objects, features, and advantages of the invention will be more explicit from the following detailed description taken with reference to the drawings wherein:

FIG. 1 is a flowchart of a method of depositing a gate dielectric by a plasma-enhanced atomic layer deposition process of the present invention comprising FIGS. 1a and 1b;

FIG. 2 is a view schematically showing a structure of a MIS capacitor of the present invention.

### DETAILED DESCRIPTION OF THE EMBODIMENTS

Now referring to the drawings, the present invention is described in detail as below.

A method of depositing a gate dielectric by a plasma-enhanced atomic layer deposition process of the present invention comprises the following steps.

Firstly, a semiconductor substrate is subjected to a cleaning process. For example, a well-cut Si substrate is put into a solution (NH₄OH:H₂O₂:H₂O=2:1:7 in volume ratio) to be ultrasonically washed for 15 minutes so as to remove metal pollutants resided on a surface thereof and is further rinsed with deionized water, followed by being kept in a diluted HF solution (HF:H₂O=1:50 in volume ratio) for about 3 minutes to remove a surface oxide resided on the Si substrate. Subsequently, the surface of the Si substrate is rinsed again with deionized water, and then is dewatered with alcohol to complete the cleaning process.

Next, the surface of the cleaned semiconductor substrate is preprocessed with oxygen plasma and nitrogen-containing plasma to form a nitrogen-containing oxide layer ii thereon.

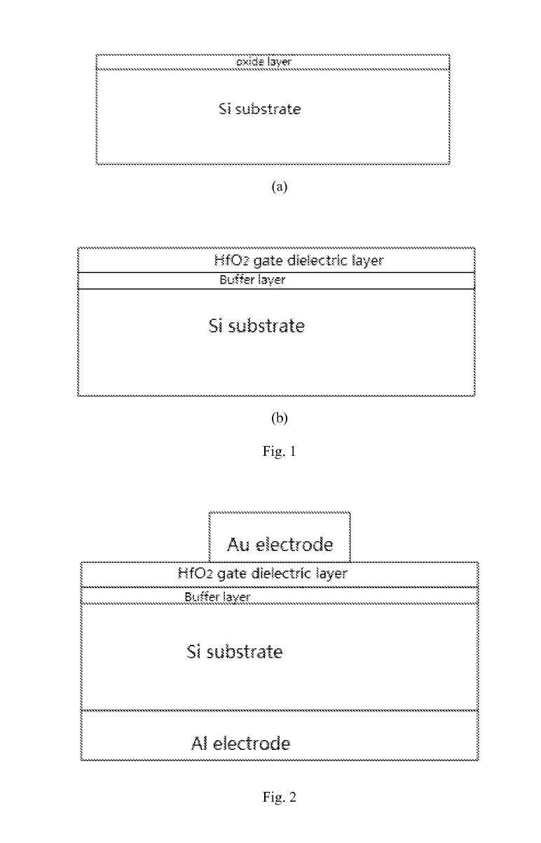

For example, the Si substrate dewatered with alcohol is immediately put into a PEALD reactor heated to 75° C., argon gas is introduced as protective gas, and an adjustment is made on gas-carrying flow matching between a transverse direction and a longitudinal direction in the PEALD reactor. Subsequently, the Si substrate is preprocessed with oxygen plasma in the PEALD reactor to remove foreign gas absorbed on the Si substrate surface and to form an ultra-thin SiO₂ layer on the Si substrate surface. Considering that a thick SiO₂ layer forming on the Si substrate surface is unfavorable for obtaining a low EOT gate dielectric film later on, the oxygen plasma is preferably set to have a power of 75 w to 100 w and an application time of 5 seconds or less so as to control the thickness of the SiO₂ layer to be formed. Subsequently, the PEALD reactor is heated to 150° C. and the Si substrate is preprocessed with ammonia plasma. Preferably, the ammonia plasma is set to have a power of 150 w to 200 w and an application time of 30 seconds or less to ensure an effective nitrogen doping. Thus, as shown in FIG. 1a, the Si substrate surface as preprocessed above has a nitrogen-containing oxide layer formed thereon.

Next, a high-k gate dielectric layer is grown by the PEALD process on the surface of the semiconductor construction which includes the above-described oxide layer. During the growth process of the gate dielectric layer, the oxide layer converts into a buffer layer of a dielectric constant higher than SiO₂. Preferably, the gate dielectric layer includes a HfO₂ gate dielectric layer, and the buffer layer includes a nitrogen-containing Hf-silicate layer.

For example, a HfO₂ gate dielectric layer of a thickness of 3 nm to 5 nm is deposited by the PEALD process on the Si substrate which has the nitrogen-containing oxide layer formed thereon. It should be noted that a sufficient hafnium source (TEMAH) is supplied during the first cycle of the PEALD reaction to ensure formation of the nitrogen-containing Hf-silicate at an interface therebetween, that is, the conversion from the nitrogen-containing SiO₂ layer into the nitrogen-containing Hf-silicate layer, so that a buffer layer is formed below the HfO₂ gate dielectric layer as shown in FIG. 1b.

Preferably, after the formation of the gate dielectric layer, the gate dielectric layer may be subjected to an oxygen plasma post-process to fill oxygen vacancies contained therein. This leads to a reduction in defect density and a decrease in leakage current in the gate dielectric.

For example, the HfO₂ gate dielectric layer as formed above is subjected to an oxygen plasma post-process with a processing power of 150 w and an application time of 30 seconds to 60 seconds to reduce the defect density and the leakage current of the HfO₂ gate dielectric layer.

In addition, a metal electrode is subsequently formed on both an upper surface and a lower surface of the semiconductor construction including the gate dielectric layer, which results in formation of a MIS capacitor.

For example, as shown in FIG. 2, on the upper surface of the Si substrate having the HfO₂ gate dielectric layer, a 100 nm thick Au layer is grown by a sputtering technique using a metallic mask of a diameter of 100 um to form an Au electrode which serves as an upper electrode of the MIS capacitor. And then, a 100 nm thick Al layer is grown by the sputtering technique on a rear face of the Si substrate to form an Al electrode which serves as a back electrode of the MIS capacitor.

The thus-formed MIS capacitor has a structure as shown in FIG. 2, including the Al electrode, the Si substrate, the Hf-silicate layer serving as a buffer layer, the HfO₂ gate dielectric layer and the Au electrode.

Preferably, the HfO₂ gate dielectric layer of the MIS capacitor has a thickness of 3 nm to 5 nm and the Hf-silicate layer has a thickness of 1 nm or less.

To sum up, the invention provides a method of depositing a gate dielectric by the plasma-enhanced atomic layer deposition process. In the method, the surface of the cleaned Si substrate is subjected to the oxygen plasma processing to form an ultra-thin SiO₂ layer thereon, and then the Si substrate surface is subjected to the ammonia plasma processing. The HfO₂ gate dielectric layer is subsequently grown by the PEALD process. At this time, the buffer layer (BL) made from nitrogen-containing Hf-silicate is formed between the Si substrate surface and the HfO₂ gate dielectric layer, which can improve interface characteristics between the HfO₂ and the Si substrate and inhibit the increase in the EOT. Large quantities of oxygen vacancies contained in the HfO₂ gate dielectric layer are filled by the oxygen plasma post-process. The HfO₂ gate dielectric layer subjected to the oxygen plasma post-process has a low defect density and a low leakage current density.

The above description of the detailed embodiments is only to illustrate the preferred implementation according to the present invention, and it is not to limit the scope of the present invention. Accordingly, all modifications and variations completed by those with ordinary skill in the art should fall within the scope of present invention defined by the appended claims.

1. A method of depositing a gate dielectric by a plasma-enhanced atomic layer deposition process, comprising:
a preprocess step of preprocessing a semiconductor substrate surface with oxygen plasma and nitrogen-containing plasma to form a nitrogen-containing oxide layer thereon; and
a growth step of growing a high-k gate dielectric layer on a surface of the nitrogen-containing oxide layer by the plasma-enhanced atomic layer deposition process, the nitrogen-containing oxide layer converting into a buffer layer of a dielectric constant higher than SiO₂ during the gate dielectric layer growth process.

2. The method of depositing a gate dielectric by the plasma-enhanced atomic layer deposition process of claim 1, further comprising a post-process step of post-processing the gate dielectric layer with oxygen plasma to fill oxygen vacancies contained therein.

3. The method of depositing a gate dielectric by the plasma-enhanced atomic layer deposition process of claim 1, wherein in the preprocess step, the semiconductor substrate surface is preprocessed with oxygen plasma and ammonia plasma to form a nitrogen-containing oxide layer thereon.

4. The method of depositing a gate dielectric by the plasma-enhanced atomic layer deposition process of claim 1, wherein the gate dielectric layer includes a HfO₂ gate dielectric layer, and the buffer layer includes a nitrogen-containing Hf-silicate layer.

5. A method of preparing an MIS capacitor, comprising:
a preprocess step of pre-processing a surface of a semiconductor substrate with oxygen plasma and nitrogen-containing plasma to form a nitrogen-containing oxide layer thereon;
a growth step of growing a high-k gate dielectric layer on the semiconductor construction surface having the oxide layer by a plasma-enhanced atomic layer deposition process, the oxide layer converting into a buffer layer of a dielectric constant higher than SiO₂ during the gate dielectric layer growth process; and
a step of forming a metal electrode on both an upper surface and a lower surface of the semiconductor construction having the gate dielectric layer deposited thereon.

6. The method of preparing an MIS capacitor of claim 5, wherein the gate dielectric layer is further subjected to an oxygen plasma post-processing to fill oxygen vacancies contained therein in the growth step.

7. The method of preparing an MIS capacitor of claim 5, wherein the gate dielectric layer is preprocessed with oxygen plasma and ammonia plasma in the preprocess step to form a nitrogen-containing oxide layer on the semiconductor substrate surface.

8. The method of preparing an MIS capacitor of claim 5, wherein the gate dielectric layer includes a HfO₂ gate dielectric layer, and the buffer layer includes a nitrogen-containing Hf-silicate layer.

9. The method of preparing an MIS capacitor of claim 5, wherein the metal electrode formed on the gate dielectric layer surface of the semiconductor construction having the gate dielectric layer deposited thereon is an Au electrode, and the metal electrode formed on an another surface of the semiconductor construction having the gate dielectric layer deposited thereon is an Al electrode.

10. A MIS capacitor, comprising a semiconductor substrate, a buffer layer of a dielectric constant higher than SiO₂ and a gate dielectric layer arranged between two metal electrodes in sequence.

11. The MIS capacitor of claim 10, wherein the gate dielectric layer includes a HfO₂ gate dielectric layer having a thickness of 3 nm to 5 nm.

12. The MIS capacitor of claim 10, wherein the buffer layer is a nitrogen-containing Hf-silicate layer having a thickness of 1 nm or less.

13. The MIS capacitor of claim 10, wherein materials of the metal electrode in contact with the semiconductor substrate contain Al.

14. The MIS capacitor of claim 10, wherein materials of the metal electrode in contact with the gate dielectric layer contain Au.

15. The method of depositing a gate dielectric by the plasma-enhanced atomic layer deposition process of claim 2, wherein in the preprocess step, the semiconductor substrate surface is preprocessed with oxygen plasma and ammonia plasma to form a nitrogen-containing oxide layer thereon.

16. The method of depositing a gate dielectric by the plasma-enhanced atomic layer deposition process of claim 2, wherein the gate dielectric layer includes a HfO₂ gate dielectric layer, and the buffer layer includes a nitrogen-containing Hf-silicate layer.

17. The method of preparing an MIS capacitor of claim 6, wherein the gate dielectric layer is preprocessed with oxygen plasma and ammonia plasma in the preprocess step to form a nitrogen-containing oxide layer on the semiconductor substrate surface.

18. The method of preparing an MIS capacitor of claim 6, wherein the gate dielectric layer includes a HfO₂ gate dielectric layer, and the buffer layer includes a nitrogen-containing Hf-silicate layer.

19. The method of preparing an MIS capacitor of claim 6, wherein the metal electrode formed on the gate dielectric layer surface of the semiconductor construction having the gate dielectric layer deposited thereon is an Au electrode, and the metal electrode formed on an another surface of the semiconductor construction having the gate dielectric layer deposited thereon is an Al electrode.

20. The MIS capacitor of claim 11, wherein the buffer layer is a nitrogen-containing Hf-silicate layer having a thickness of 1 nm or less.

21. The MIS capacitor of claim 11, wherein materials of the metal electrode in contact with the semiconductor substrate contain Al.

22. The MIS capacitor of claim 11, wherein materials of the metal electrode in contact with the gate dielectric layer contain Au.
